(19) United States
(12) Patent Application Publication
(10) Pub. No.: US 2026/0143724 A1
(43) Pub. Date: May 21, 2026

(54) SEMICONDUCTOR DEVICE AND MANUFACTURING METHOD THEREFOR

(71) Applicant: CANON KABUSHIKI KAISHA, Tokyo (JP)

(72) Inventors: MASAHIKO SONE, Tokyo (JP); AKINORI MAKAINO, Kanagawa (JP)

(21) Appl. No.: 19/380,212

(22) Filed: Nov. 5, 2025

(30) Foreign Application Priority Data
Nov. 15, 2024 (JP) 2024-200021

(51) Int. Cl. H10D 1/00; H10D 1/68

(52) U.S. Cl. CPC H10D 1/043; H10D 1/042; H10D 1/68

(57) ABSTRACT

A method for manufacturing a semiconductor device includes forming a structure having a capacitor on a first interlayer dielectric film; and forming a second interlayer dielectric film made of a cured product of a curable composition by arranging the curable composition on the structure, bringing a superstrate into contact with the curable composition, and curing the curable composition, wherein the structure includes a pixel array region and a peripheral region, the capacitor being arranged on the pixel array region, and in the forming the second interlayer dielectric film, the curable composition is arranged on the structure so as to make an area density of the curable composition arranged on the pixel array region become lower than an area density of the curable composition arranged on the peripheral region.

### BACKGROUND

### Field of the Technology

The present disclosure relates to a semiconductor device and a manufacturing method therefor.

### Description of the Related Art

Japanese Patent Laid-Open No. 2007-188935 discloses a semiconductor device including MIM capacitive elements arranged on a lower interlayer dielectric film arranged on a silicon substrate and including an upper interlayer dielectric film arranged on the substrate so as to cover the lower interlayer dielectric film and the MIM capacitive element. Each MIM capacitive element includes a lower metal electrode arranged on the lower interlayer dielectric film, a capacitive insulating film arranged on the lower metal electrode, and an upper metal electrode arranged on the capacitive insulating film.

In the above semiconductor device, a large stepped portion can be formed by the lower metal electrode, the capacitive insulating film, and the upper metal electrode. Accordingly, it is necessary to planarize a surface of the upper interlayer dielectric film arranged to cover the stepped portion. For this purpose, it is necessary to increase the thickness of the upper interlayer dielectric film or planarize the upper interlayer dielectric film by a CMP step. Accordingly, a semiconductor device like that described above can make the manufacturing method more complex.

### SUMMARY

The present disclosure provides a technique advantageous in planarizing an interlayer dielectric film covering capacitors.

The present disclosure includes a method for manufacturing a semiconductor device, the method comprising: forming a structure having a capacitor on a first interlayer dielectric film; and forming a second interlayer dielectric film made of a cured product of a curable composition by arranging the curable composition on the structure, bringing a superstrate into contact with the curable composition, and curing the curable composition, wherein the structure includes a pixel array region and a peripheral region, the capacitor being arranged on the pixel array region, and in the forming the second interlayer dielectric film, the curable composition is arranged on the structure so as to make an area density of the curable composition arranged on the pixel array region become lower than an area density of the curable composition arranged on the peripheral region.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the arrangement of a planarization apparatus;

FIG. 2 is a view schematically showing the arrangement of an imprint apparatus;

FIG. 3 is a sectional view schematically and exemplarily showing a manufacturing step for a semiconductor device;

FIG. 4 is a sectional view schematically and exemplarily showing a manufacturing step for the semiconductor device;

FIG. 5 is a sectional view schematically and exemplarily showing a manufacturing step for the semiconductor device;

FIG. 6 is a sectional view schematically and exemplarily showing a manufacturing step for the semiconductor device;

FIG. 7 is a sectional view schematically and exemplarily showing a manufacturing step for the semiconductor device;

FIG. 8 is a sectional view schematically and exemplarily showing a manufacturing step for the semiconductor device;

FIG. 9 is a sectional view schematically and exemplarily showing a manufacturing step for the semiconductor device;

FIG. 10 is a sectional view schematically and exemplarily showing a manufacturing step for the semiconductor device;

FIG. 11 is a sectional view schematically and exemplarily showing a manufacturing step for the semiconductor device;

FIG. 12 is a sectional view schematically and exemplarily showing a manufacturing step for the semiconductor device;

FIG. 13 is a sectional view schematically and exemplarily showing a manufacturing step for the semiconductor device;

FIG. 14 is a sectional view schematically and exemplarily showing a manufacturing step for the semiconductor device;

FIG. 15 is a sectional view schematically and exemplarily showing a manufacturing step for the semiconductor device;

FIG. 16 is a sectional view schematically and exemplarily showing a manufacturing step for the semiconductor device; and

FIG. 17 is a sectional view schematically and exemplarily showing a manufacturing step for the semiconductor device.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

Before a description of a manufacturing method for a semiconductor device according to the present embodiment, a planarization apparatus and an imprint apparatus which can be used in the manufacturing method will be exemplarily described first. The planarization apparatus and the imprint apparatus each are an apparatus that forms a film made of a cured product of a curable composition by applying curing energy to the curable composition arranged on a substrate. A curable composition is a composition to be cured by receiving curing energy. As the curing energy, an electromagnetic wave, heat, or the like can be used. The electromagnetic wave can be, for example, light selected from the wavelength range of 10 nm (inclusive) to 1 mm (inclusive), such as infrared rays, visible light, or ultraviolet light. The curable composition may be understood as a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition can be arranged on the substrate in the form of droplets or in the form of an island or film formed by connecting a plurality of droplets. Alternatively, the curable composition may be supplied onto the substrate in the form of a film by a spin coater or a slit coater. The viscosity (the viscosity at 25°C) of an imprint material can be, for example, from 1 mPa∙s (inclusive) to 100 mPa∙s (inclusive).

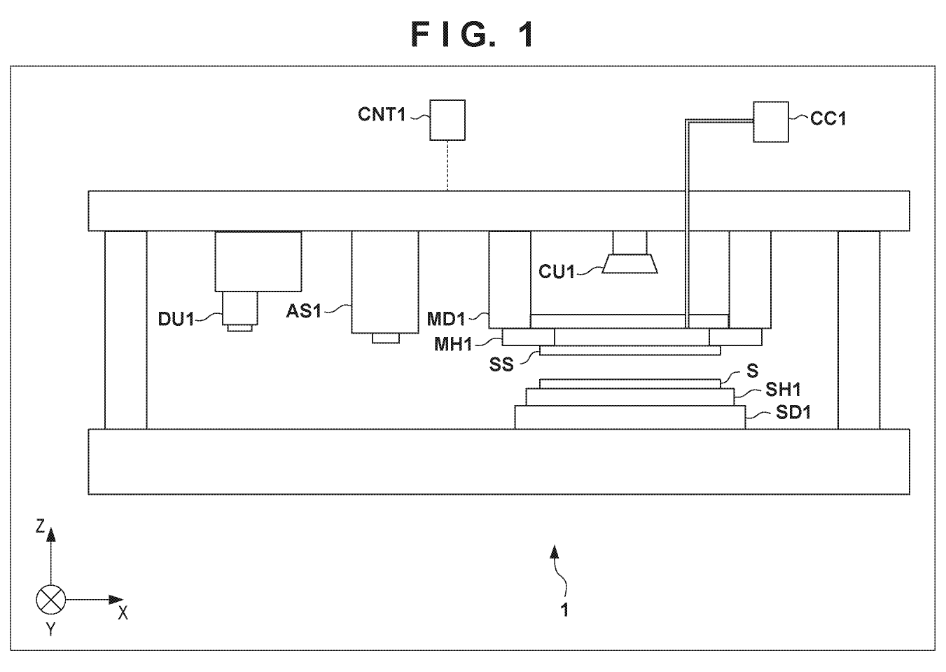

FIG. 1 schematically shows the arrangement of a planarization apparatus 1. The planarization apparatus 1 can include a substrate holder SH1 that holds the substrate S, and a substrate driving mechanism SD1 that drives the substrate S by driving the substrate holder SH1. The substrate driving mechanism SD1 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The planarization apparatus 1 can include a mold holder MH1 that holds superstrate SS as a mold having a surface to be planarized and a mold driving mechanism MD1 that drives the superstrate SS by driving the mold holder MH1. The mold driving mechanism MD1 can be configured to drive the superstrate SS with respect to a plurality of axes (for example, three axes including the Z-axis, θX-axis, and θY-axis, and preferably six axes including the X-axis, Y-axis, Z-axis, θX-axis, θY-axis, and θZ-axis).

The planarization apparatus 1 can also include the shape controller CC1 that controls the shape related to the Z-axis of the superstrate SS held by the mold holder MH1. For example, the shape controller CC1 can control the shape related to the Z-axis of the superstrate SS by adjusting the pressure on the rear surface (the surface on the opposite side of the surface including the pattern region contacting the curable composition) of the superstrate SS held by the mold holder MH1. When bringing the pattern region of the superstrate SS into contact with the curable composition on the substrate S, the shape of the superstrate SS can normally be controlled by the shape controller CC1 so as to be convex downward.

The planarization apparatus 1 can also include a curing unit CU1 that cures the curable composition by irradiating, with curing energy, the curable composition filled into the space between the superstrate SS and the plurality of shot regions of the substrate S. In addition, the planarization apparatus 1 can include a dispenser DU1 that arranges the first curable composition on the plurality of shot regions of the substrate S. Note that the substrate S with the curable composition arranged on the plurality of shot regions may be loaded or supplied into the planarization apparatus 1. In this case, the dispenser DU1 need not be provided. The planarization apparatus 1 can include an alignment scope AS1. The alignment scope AS1 can be used to detect the position of an alignment mark provided on the substrate S.

The planarization apparatus 1 can further include a controller CNT1 that controls the substrate holder SH1, the substrate driving mechanism SD1, the mold holder MH1, the mold driving mechanism MD1, the curing unit CU1, the dispenser DU1, the alignment scope AS1, a shape controller CC1, and the like. The controller CNT1 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

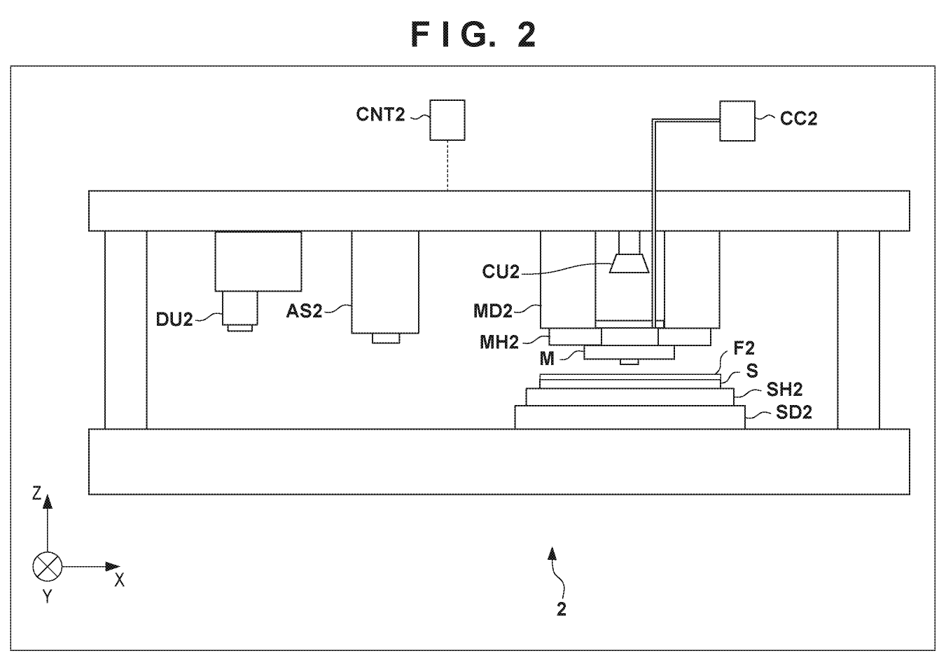

FIG. 2 schematically shows the arrangement of an imprint apparatus 2. The imprint apparatus 2 can include a substrate holder SH2 that holds the substrate S on which the first film F1 has been formed, and a substrate driving mechanism SD2 that drives the substrate S by driving the substrate holder SH2. The substrate driving mechanism SD2 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis).

The imprint apparatus 2 can also include a mold holder MH2 that holds the mold M having a transfer surface with a three-dimensional structure to be transferred to a curable composition and a mold driving mechanism MD2 that drives the mold M by driving the mold holder MH2. The mold driving mechanism MD2 can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis). The imprint apparatus 2 can also include a shape controller CC2 that controls the shape related to the Z-axis of the mold M held by the mold holder MH2. For example, the shape controller CC2 can control the shape related to the Z-axis of the mold M by adjusting the pressure on the rear surface (the surface on the opposite side of the surface including the pattern region contacting the curable composition) of the mold M held by the mold holder MH2. When bringing the transfer surface of the mold M into contact with the curable composition on the substrate S, the shape of the mold M can be controlled by the shape controller CC2 so as to be convex downward.

The imprint apparatus 2 can also include a curing unit CU2 that cures the curable composition by irradiating, with curing energy, the curable composition filled into the space between the mold M and the shot region of the substrate S. In addition, the imprint apparatus 2 can include a dispenser DU2 that arranges the second curable composition on the shot region of the substrate S. Note that the substrate S with the curable composition arranged on the plurality of shot regions may be loaded or supplied into the imprint apparatus 2. In this case, the dispenser DU2 need not be provided. The imprint apparatus 2 can include an alignment scope AS2. The alignment scope AS2 can be used to detect the position of an alignment mark provided on the substrate S.

The imprint apparatus 2 can further include a controller CNT2 that controls the substrate holder SH2, the substrate driving mechanism SD2, the mold holder MH2, the mold driving mechanism MD2, the curing unit CU2, the dispenser DU2, the alignment scope AS2, the shape controller CC2, and the like. The controller CNT2 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

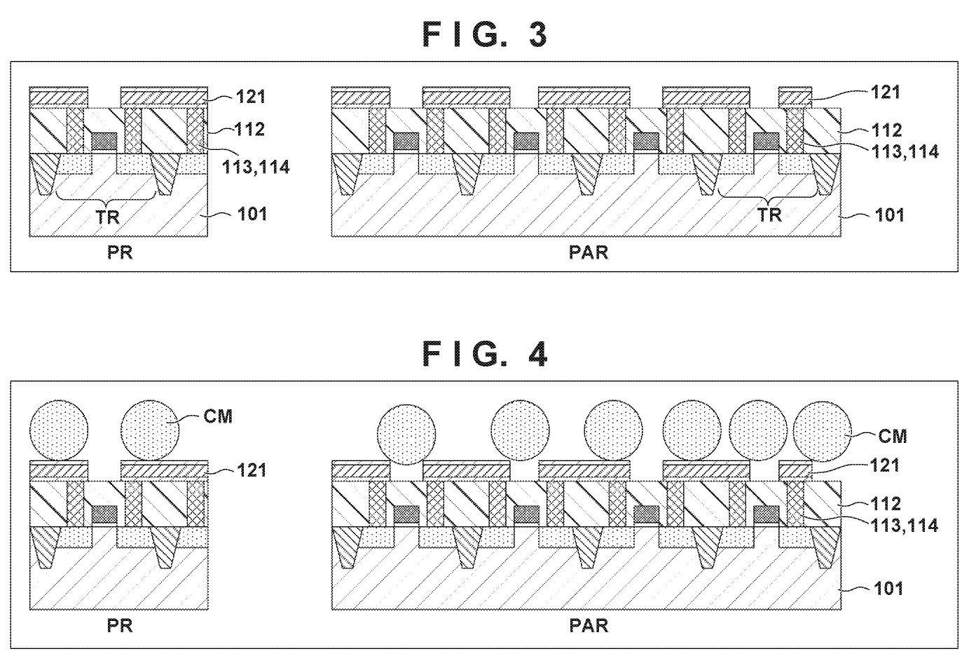

A semiconductor device and a manufacturing method therefor according to an embodiment will be described below with reference to FIGS. 3 to 17. Although a semiconductor device including a pixel array region PAR having a plurality of pixels and a peripheral region PR and a manufacturing method therefor will be exemplarily described below, the present disclosure is not limited to them and can also be applied to a semiconductor device that does not have such arrangement and a manufacturing method therefor. Such a semiconductor device can be, for example, a processor that processes digital data and/or analog data. The processor is broadly interpreted and can include, for example, a device such as a CPU, MPU, image processing device, AD converter, DA converter, sensor, or memory. Unless explicitly defined otherwise, a pixel is broadly interpreted as an element having a function of detecting light and/or a function of generating light. In the following description, matters that are not described as essential requirements in the present disclosure do not limit the present disclosure.

In the step exemplarily shown in FIG. 3, an element such as a transistor TR and element isolation (for example, STI) are formed on a semiconductor substrate 101, and an interlayer dielectric film 112 is formed on the semiconductor substrate 101. A contact hole 113 is formed in the interlayer dielectric film 112. A contact plug 114 can be arranged in the contact hole 113. In the step shown in FIG. 3, a wiring pattern 121 can be further formed on the interlayer dielectric film 112. In this case, the wiring pattern 121 can have a multilayer structure. Although not shown, a photoelectric conversion element and/or a light-emitting element is formed on a portion, of the semiconductor substrate 101, which forms the pixel array region PAR.

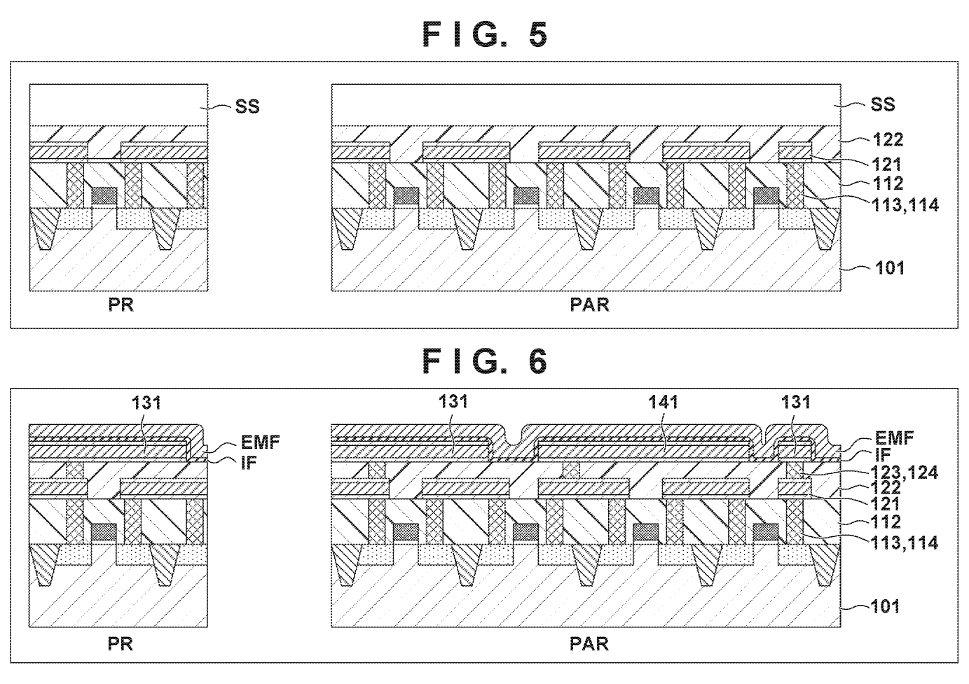

In the steps exemplarily shown in FIGS. 4 and 5, an interlayer dielectric film (first interlayer dielectric film) 122 can be formed. In the example shown in FIGS. 4 and 5, the interlayer dielectric film 122 can be formed from a curable composition such as a photo-curable composition. More specifically, in the step exemplarily shown in FIG. 4, in the planarization apparatus 1, a curable composition CM can be arranged on the interlayer dielectric film 112 and the wiring pattern 121. In the step exemplarily shown in FIG. 5, a cured film formed of a cured product of the curable composition CM can be formed as the interlayer dielectric film 122 by bringing the superstrate SS into contact with the curable composition CM and applying curing energy to the curable composition CM. Thereafter, the superstrate SS can be separated from the interlayer dielectric film 122. Note that one or a plurality of interlayer dielectric films may be arranged between the semiconductor substrate 101 and the interlayer dielectric film 122.

The interlayer dielectric film 122 may be formed of an inorganic material film instead of the cured film of the curable composition CM. The inorganic material film can include, for example, at least one of a phosphor silicate glass (PSG) film, boron phosphor silicate glass (BPSG) film, and spin on glass (SOG) film. One or a plurality of interlayer dielectric films that can be arranged between the semiconductor substrate 101 and the interlayer dielectric film 122 can also be formed of such an inorganic material film.

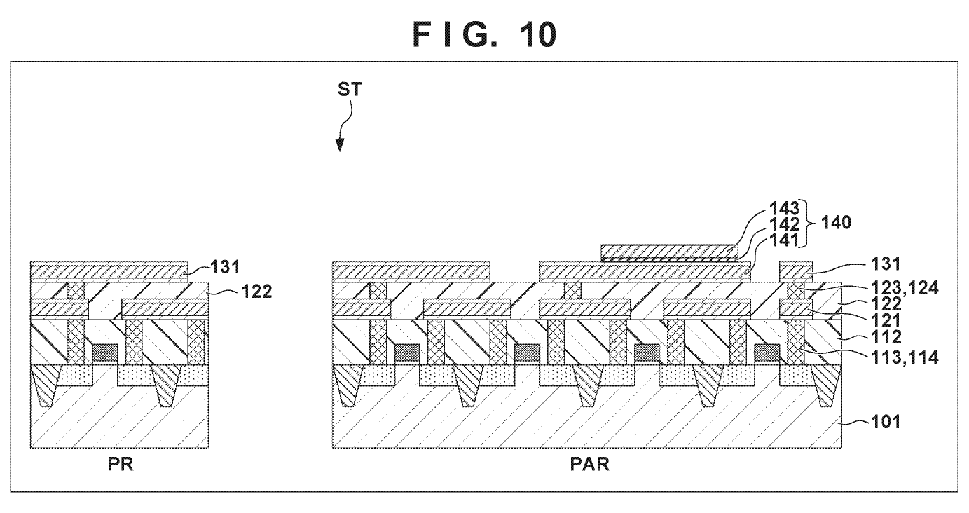

In the step exemplarily shown in FIG. 6, a wiring pattern 131 and a lower electrode 141 of a capacitor 140 (see FIG. 10 or the like) can be formed on the interlayer dielectric film 122. The wiring pattern 131 and the lower electrode 141 of the capacitor 140 can be formed by forming a conductive film on the interlayer dielectric film 122 and patterning the conductive film by an imprint process or photolithography process. In this case, although the wiring pattern 131 is formed together with the lower electrode 141 in the step of forming the lower electrode 141, the wiring pattern 131 may be formed in a step different from the step of forming the lower electrode 141. In the step exemplarily shown in FIG. 6, an insulating film IF can be formed so as to cover the interlayer dielectric film 122, the wiring pattern 131, and the lower electrode 141, and an electrode material film EMF can be formed so as to cover the insulating film IF.

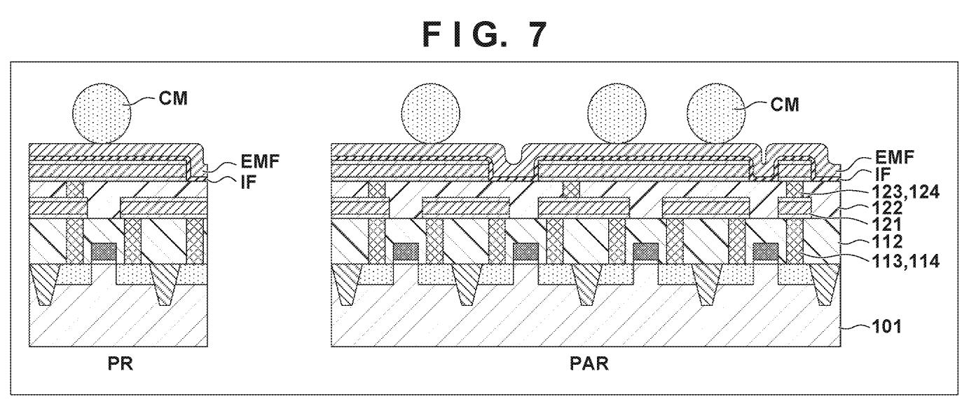

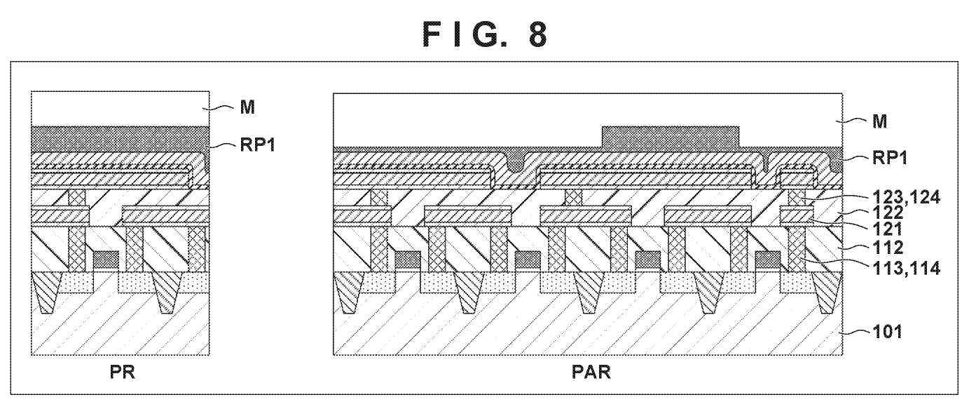

In the patterning step exemplarily shown in FIGS. 7, 8, 9, and 10, an upper electrode 143 can be formed on the capacitor 140 by patterning the electrode material film EMF. In this patterning step, the insulating film IF can also be patterned next to the electrode material film EMF. In this patterning step, the upper electrode 143 can be formed by forming a resist pattern on the electrode material film EMF by an imprint process and etching the electrode material film EMF by using the resist pattern as an etching mask.

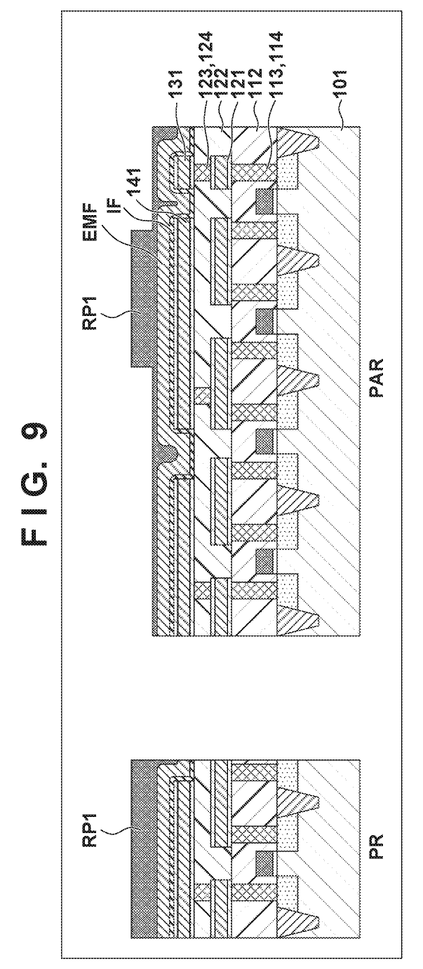

More specifically, in the step exemplarily shown in FIG. 7, the curable composition CM can be arranged on the electrode material film EMF in the imprint apparatus 2. In the steps exemplarily shown in FIGS. 8 and 9, a cured film made of a cured product of the curable composition can be formed as a resist pattern RP1 by bringing the mold M into contact with the curable composition CM on the electrode material film EMF and applying curing energy to the curable composition CM. Thereafter, the mold M can be separated from the resist pattern RP1. In the steps exemplarily shown in FIGS. 9 and 10, the electrode material film EMF can be formed by using the resist pattern RP1 as an etching mask, and the upper electrode 143 and an insulating film (capacitor insulating film) 142 can be further formed by etching the insulating film IF. With these steps, the capacitor 140 including the lower electrode 141, the insulating film 142, and the upper electrode 143 is formed. In the above manner, a structure ST including the capacitor 140 can be formed on the interlayer dielectric film 122. The capacitor 140 can have a metal-insulator-metal (MIM) structure. A series of steps exemplarily shown in FIGS. 3 to 10 can be understood as a structure forming step of forming the structure ST.

In a case where the insulating film IF and the electrode material film EMF are formed after the formation of the lower electrode 141 and the wiring pattern 131, a concave-convex portion can be formed on a surface of the electrode material film EMF due to the influences of the lower electrode 141 and the wiring pattern 131. Accordingly, the resist pattern RP1 can be formed without forming a new planarized film on the electrode material film EMF by applying an imprint process for patterning the electrode material film EMF.

In a case where the flatness of the surface of the electrode material film EMF can be allowed or a planarized film is allowed to be formed on the electrode material film EMF, a patterning step of patterning the electrode material film EMF may be performed by a photolithography process. In this case, the patterning step can include a step of forming a resist pattern on an electrode material film by a photolithography process and a step of forming the upper electrode 143 by etching the electrode material film using the resist pattern as an etching mask.

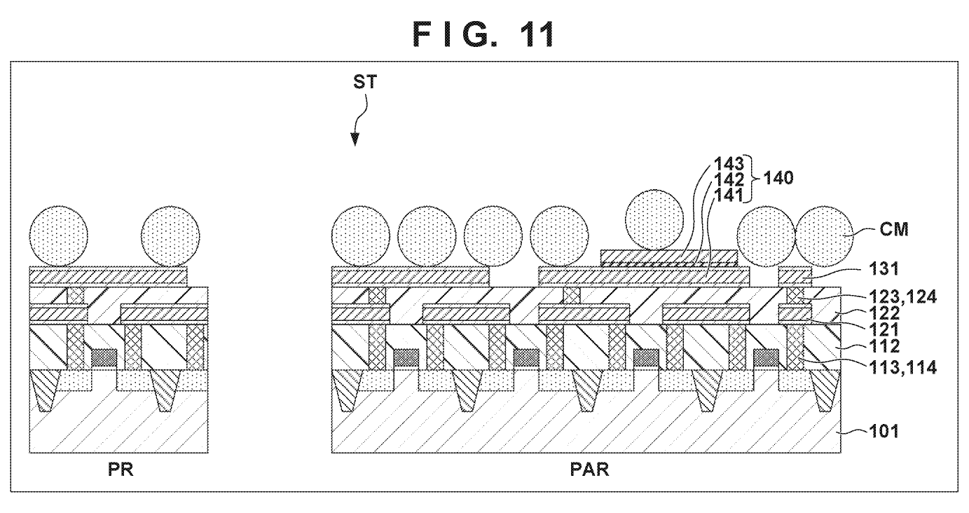

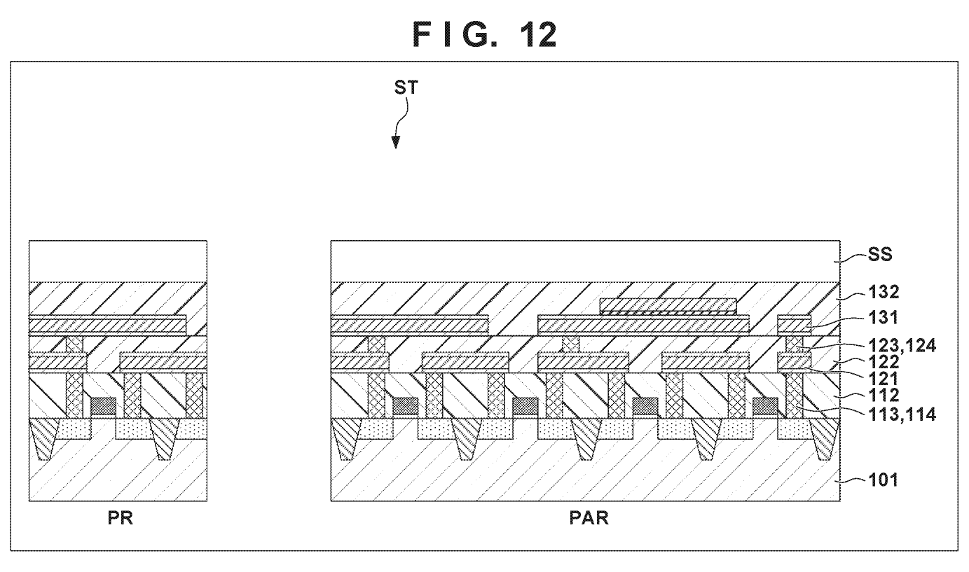

In the insulating film forming steps exemplarily shown in FIGS. 11 and 12, an interlayer dielectric film 132 can be formed. More specifically, in the step exemplarily shown in FIG. 11, the curable composition CM can be arranged on the structure ST in the planarization apparatus 1. In this case, in the peripheral region PR, the area density distribution of the curable composition CM arranged on the structure ST is preferably adjusted in a design without any capacitor like the capacitor 140 on the peripheral region PR. More specifically, the curable composition CM is preferably arranged on the structure ST such that the area density of the curable composition CM arranged on the pixel array region PAR is lower than that of the curable composition CM arranged on the peripheral region PR. An area density can be the number of droplets of the curable composition CM arranged per unit area or the volume of the curable composition CM arranged per unit area.

In the step exemplarily shown in FIG. 12, a cured film formed of a cured product of the curable composition CM can be formed as the interlayer dielectric film 132 by bringing the superstrate SS into contact with the curable composition CM and applying curing energy to the curable composition CM. Thereafter, the superstrate SS can be separated from the interlayer dielectric film 132. Note that the curable composition CM used to form the interlayer dielectric film 122 and the curable composition CM used to form the interlayer dielectric film 132 may be the same or different from each other. In addition, the planarization apparatus 1 used to form the interlayer dielectric film 122 and the planarization apparatus 1 used to form the interlayer dielectric film 132 may be the same or different from each other. Furthermore, the superstrate SS used to form the interlayer dielectric film 122 and the superstrate SS used to form the interlayer dielectric film 132 may be the same or different from each other. The interlayer dielectric film 132 having a flat surface can be easily formed by forming the interlayer dielectric film 132 covering the interlayer dielectric film 122, the wiring pattern 131, and the capacitor 140 using the planarization apparatus 1. This is advantageous in reducing the manufacturing cost and improving the throughput.

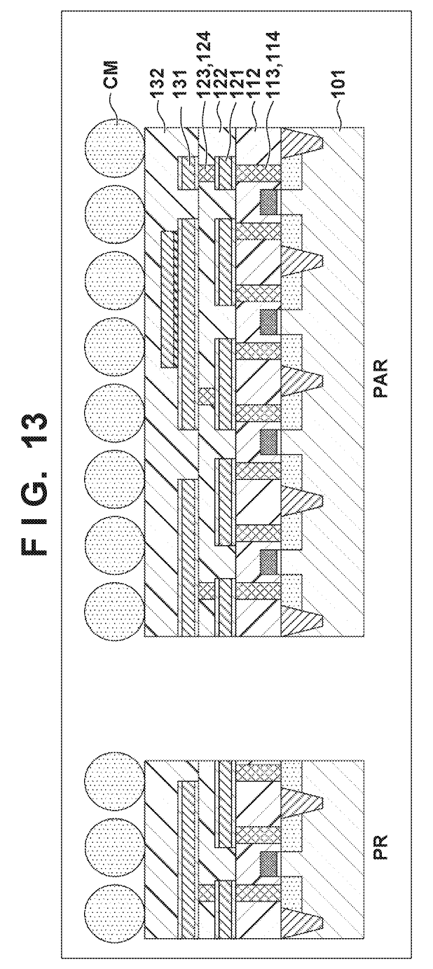

In the via hole forming steps exemplarily shown in FIGS. 13, 14, 15, and 16, via holes 133, 135, and 137 can be formed in the interlayer dielectric film 132. In via hole forming steps, the via holes 133, 135, and 137 can be formed by forming a resist pattern on the interlayer dielectric film 132 by an imprint process and etching the electrode material film EMF by using the resist pattern as an etching mask.

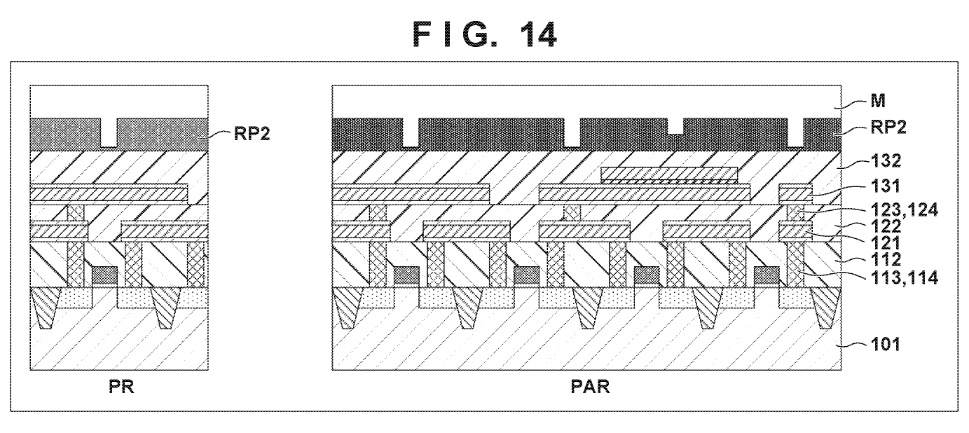

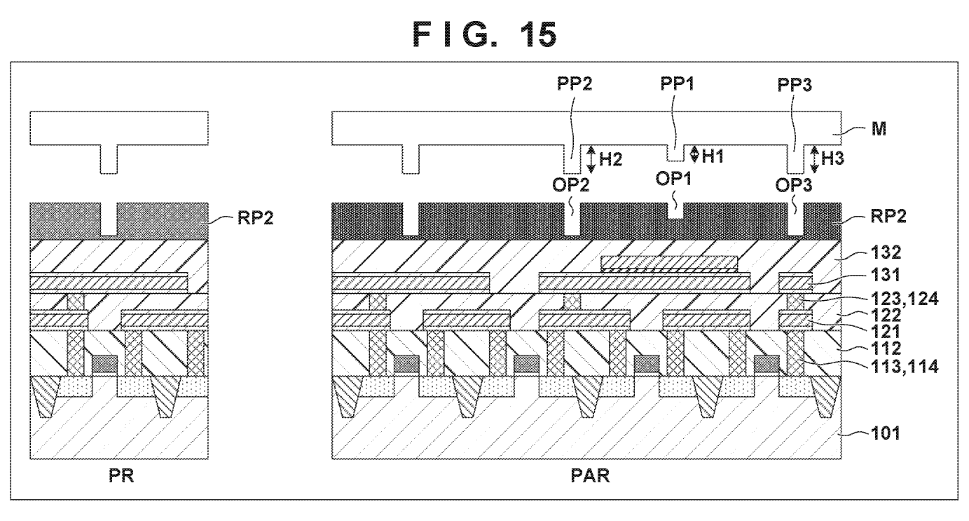

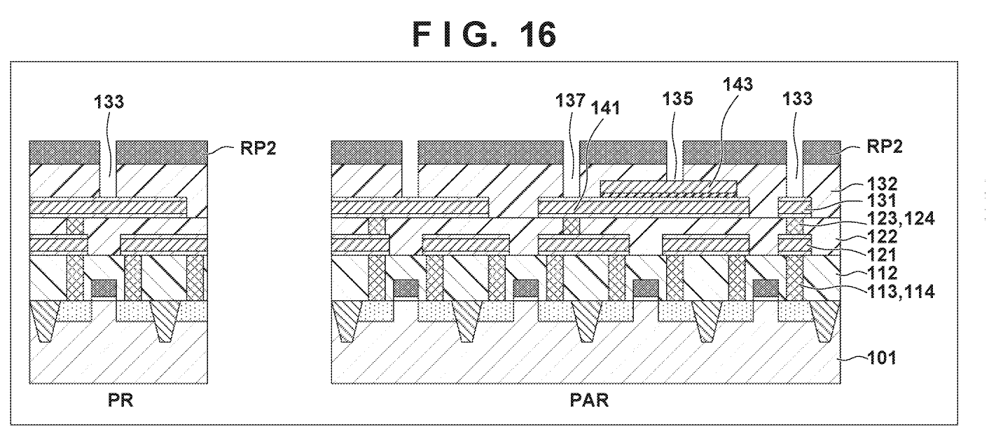

More specifically, in the step exemplarily shown in FIG. 13, the curable composition CM can be arranged on the interlayer dielectric film 132 in the imprint apparatus 2. Subsequently, in the step exemplarily shown in FIG. 14, a cured film formed of a cured product of the curable composition CM can be formed as a resist pattern RP2 by bringing the mold M into contact with the curable composition CM on the interlayer dielectric film 132 and applying curing energy to the curable composition CM. In the step exemplarily shown in FIG. 15, the mold M can be separated from the resist pattern RP2. Openings OP1, OP2, and OP3 can be formed in a resist pattern RP3 by transferring convex portions PP1, PP2, and PP3 of the mold M. In the step exemplarily shown in FIG. 16, the via holes 135, 137, and 133 can be formed by etching the interlayer dielectric film 132 through the openings OP1, OP2, and OP3.

In this case, the mold M can have the convex portion PP1 for the formation of the first via hole 135 to partially expose the upper electrode 143. In addition, the mold M can have the convex portion PP2 for the formation of the second via hole 137 to partially expose the lower electrode 141. The mold M can also include the convex portion PP3 for the formation of the third via hole 133 to partially expose the wiring pattern 131. The convex portion PP1 has a height difference H1. The convex portion PP2 has a height difference H2. The convex portion PP3 has a height difference H3. The height difference H1 of the convex portion PP1 is smaller than the height difference H2 of the convex portion PP2 and the height difference H3 of the convex portion PP3. Such height differences depend on the depths of via holes 135, 137, and 133 to be formed. Adjusting the height differences H1, H2, and H3 of the convex portions PP1, PP2, and PP3 makes it possible to end the etching for the formation of the via holes 135, 137, and 133 at almost the same time and hence to prevent excessive etching. This is advantageous in, for example, reducing etching damage to the capacitor 140.

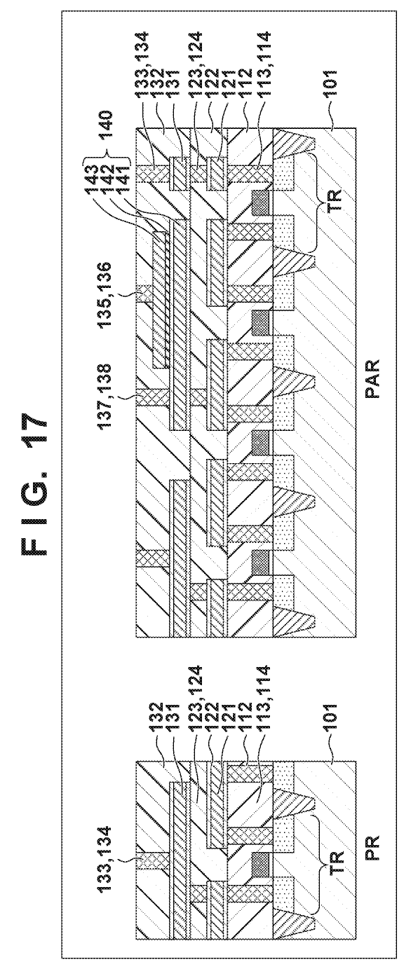

In the step exemplarily shown in FIG. 17, via plugs 136, 138, and 134 can be formed by filling the via holes 135, 137, and 133 with a conductive material. In the subsequent steps, for example, interlayer dielectric films, wiring patterns, via holes, and via plugs can be formed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-200021, filed November 15, 2024, which is hereby incorporated by reference herein in its entirety.

What is claimed is:

1. A method for manufacturing a semiconductor device, the method comprising:
forming a structure having a capacitor on a first interlayer dielectric film; and
forming a second interlayer dielectric film made of a cured product of a curable composition by arranging the curable composition on the structure, bringing a superstrate into contact with the curable composition, and curing the curable composition,
wherein the structure includes a pixel array region and a peripheral region, the capacitor being arranged on the pixel array region, and
in the forming the second interlayer dielectric film, the curable composition is arranged on the structure so as to make an area density of the curable composition arranged on the pixel array region become lower than an area density of the curable composition arranged on the peripheral region.

2. The method according to claim 1, wherein the forming the structure includes
forming a lower electrode of the capacitor on the first interlayer dielectric film,
forming an insulating film so as to cover the lower electrode,
forming an electrode material film so as to cover the insulating film, and
forming an upper electrode of the capacitor by patterning the electrode material film.

3. The method according to claim 2, wherein the patterning includes forming a resist pattern on the electrode material film by an imprint process, and
etching the electrode material film by using the resist pattern as an etching mask.

4. The method according to claim 2, wherein the forming the upper electrode of the capacitor includes
forming a resist pattern on the electrode material film by a photolithography process, and
forming the upper electrode by etching the electrode material film by using the resist pattern as an etching mask.

5. The method according to claim 2, wherein in the forming the upper electrode of the capacitor, the insulating film is patterned next to the electrode material film.

6. The method according to claim 2, wherein in the forming the lower electrode, a wiring pattern is formed together with the lower electrode.

7. The method according to claim 6, further comprising forming a first via hole to partially expose the upper electrode and a second via hole to partially expose the lower electrode.

8. The method according to claim 7, wherein the forming the first via hole includes
forming a second resist pattern on the second interlayer dielectric film by an imprint process using a mold, and
forming the first via hole and the second via hole by etching the second interlayer dielectric film using the second resist pattern,
wherein the mold includes a first convex portion for formation of the first via hole and a second convex portion for formation of the second via hole, the first convex portion having a height difference smaller than a height difference of the second convex portion.

9. The method according to claim 6, further comprising forming a first via hole to partially expose the upper electrode and a second via hole to partially expose the wiring pattern.

10. The method according to claim 7, wherein the forming the first via hole includes
forming a second resist pattern on the second interlayer dielectric film by an imprint process using a mold, and
forming the first via hole and the second via hole by etching the second interlayer dielectric film by using the second resist pattern,
wherein the mold includes a first convex portion for formation of the first via hole and a second convex portion for formation of the second via hole, the first convex portion having a height difference smaller than a height difference of the second convex portion.

11. The method according to claim 6, further comprising forming a first via hole to partially expose the upper electrode, a second via hole to partially expose the lower electrode, and a third via hole to partially expose the wiring pattern.

12. The method according to claim 11, wherein the forming the first via hole includes
forming a second resist pattern on the second interlayer dielectric film by an imprint process using a mold, and
forming the first via hole, the second via hole, and the third via hole by etching the second interlayer dielectric film using the second resist pattern, and
the mold includes a first convex portion for formation of the first via hole, a second convex portion for formation of the second via hole, and a third convex portion for formation of the third via hole, the first convex portion having a height difference smaller than a height difference of the second convex portion and a height difference of the third convex portion.

13. The method according to claim 1, wherein the forming the structure includes forming an interlayer dielectric film formed of a cured product of a second curable composition as the first interlayer dielectric film by bringing a superstrate into contact with the second curable composition and curing the second curable composition.

14. A method for manufacturing a semiconductor device, the method comprising:
forming a structure having a capacitor on a first interlayer dielectric film; and
forming a second interlayer dielectric film made of a cured product of a curable composition by arranging the curable composition on the structure, bringing a superstrate into contact with the curable composition, and curing the curable composition,
wherein the forming the structure includes
forming a lower electrode of the capacitor on the first interlayer dielectric film,
forming an insulating film so as to cover the lower electrode,
forming an electrode material film so as to cover the insulating film,
forming a resist pattern on the electrode material film by an imprint process, and
forming an upper electrode of the capacitor by etching the electrode material film using the resist pattern as an etching mask.

15. A semiconductor device comprising:
a semiconductor substrate on which a plurality of transistors are arranged;
a first interlayer dielectric film arranged on the semiconductor substrate;
a capacitor arranged on the first interlayer dielectric film; and
a second interlayer dielectric film covering the first interlayer dielectric film and the capacitor,
wherein the second interlayer dielectric film is formed from a curable composition.

16. The device according to claim 15, wherein the first interlayer dielectric film is formed from a curable composition.

17. The device according to claim 15, wherein the curable composition forming the second interlayer dielectric film is a photo-curable composition.

18. The device according to claim 17, wherein the first interlayer dielectric film includes an inorganic material film.

19. The device according to claim 15, further comprising one or a plurality of interlayer dielectric films arranged between the semiconductor substrate and the first interlayer dielectric film,
wherein the one or the plurality of interlayer dielectric films includes an inorganic material film.
